(19) United States
(12) Patent Application Publication
(10) Pub. No.: US 2014/0318626 A1
(43) Pub. Date: Oct. 30, 2014

(54) HIGH-CONDUCTIVITY HOLE TRANSPORT MATERIAL AND DYE-SENSITIZED SOLAR CELL USING SAME

(71) Applicants: Taiho Park, Gyungbuk (KR); In Young Song, Incheon (KR)

(72) Inventors: Taiho Park, Gyungbuk (KR); In Young Song, Incheon (KR)

(73) Assignee: POSTECH ACADEMY-INDUSTRY FOUNDATION, Pohang-si (KR)

(21) Appl. No.: 14/236,402

(22) PCT Filed: Jan. 31, 2012
(86) PCT No.: PCT/KR2012/000745

§ 371 Date: Apr. 9, 2014

(30) Foreign Application Priority Data
Aug. 4, 2011 (KR) 10-2011-0077700

(51) Int. Cl. H01G 9/20; H01L 51/00

(52) U.S. Cl. CPC H01G 9/2031; H01L 51/0071
USPC 136/263; 549/50; 568/610; 549/59; 252/500; 438/82

(57) ABSTRACT

The present invention provides a high-conductivity hole transport material for reducing a photoelectron recombination reaction, and a solid-state dye-sensitized solar cell. The hole transport material is formed by using a compound having the structure of chemical formula (1) or (2) according to the present invention. The solid-state dye-sensitized solar cell comprises a hole transport material layer, which is formed by coating the compound on an inorganic oxide layer by means of photoelectrochemical polymerization or by means of thermal polymerization.

### TECHNICAL FIELD

The present invention relates to a high-conductivity hole transport material for reducing a photoelectron recombination reaction and a dye-sensitized solar cell using the same. More particularly, the present invention relates to a novel hole transport material which may reduce a photoelectron recombination reaction and has improved conductivity, and to a solid-state dye-sensitized solar cell having a polymer conductive layer formed by photoelectrochemical polymerization or thermal polymerization of the hole transport material, without the use of corrosive iodine and an iodine ion.

### BACKGROUND ART

A device for converting solar light into energy so as to directly produce electric power refers to a solar cell device. This is based on the fact that, since the first observation of the photovoltaic effect by French Physicist Becquerel in 1839, a phenomenon similar thereto was found in a solid such as selenium. In 1991, the Gratzel research team in Switzerland published a dye-sensitized solar cell (DSSC) having a light-to-electrical conversion efficiency of about 10%, manufactured by chemically adsorbing a Ru(phophyrine) dye onto a nanocrystalline anatase TiO₂-based semiconductor thin film and utilizing, as an electrolyte, a solution containing iodine and an iodine salt. The dye-sensitized solar cell, having superior light-to-electrical conversion efficiency, is regarded as the most advanced technique able to replace currently available silicon diodes.

Typically, a dye-sensitized solar cell includes a semiconductor electrode formed by coating a highly conductive fluorine (F)- or indium (In)-doped inorganic oxide electrode with a semiconductor comprising dye-adsorbed porous titanium dioxide (TiO₂) nanoparticles, a counter electrode coated with platinum (Pt) or carbon (C), and an electrolyte loaded between the above two electrodes. The dye-sensitized solar cell is configured such that the dye-adsorbed inorganic oxide layer and the electrolyte or the hole transport material are inserted between the transparent electrode and the metal electrode and thus a photoelectrochemical reaction is carried out. The manufacturing cost of the dye-sensitized solar cell is lower by about 20% than that of silicon solar cells, but such a dye-sensitized solar cell may exhibit high light-to-electrical conversion efficiency comparable with that of amorphous silicon-based solar cells, and is thus reported to have very high commercialization potential. U.S. Pat. Nos. 4,927,721 and 5,350,644.

The dye-sensitized solar cell, especially a solid-state dye-sensitized solar cell using a solid electrolyte or a hole transport material (HTM) is reported to supplement the disadvantages of a dye-sensitized solar cell using a solution electrolyte, including a short lifespan and a drastic decrease in efficiency due to leakage of the solution electrolyte. As published by the Yanagida research team in 1997, a dye-sensitized solar cell is configured such that a dye-adsorbed semiconductor electrode is coated with a conductive material by photoelectrochemical polymerization using photoelectrochemical properties, and a small amount of an ionic liquid electrolyte containing a metal salt is applied on the conductive material-coated semiconductor electrode before formation of a counter electrode. Murakoshi K, Kogure R, Wada Y, and Yanagida S, Chem. Lett., 5, 471 (1997).

A coating of the conductive material by photoelectrochemical polymerization is formed by, with the dye-adsorbed semiconductor electrode and the counter electrode such as Pt being immersed in a dissolved solution of a conductive material precursor and an electrolyte, irradiating light having a wavelength able to excite the dye, and applying current or voltage to both electrodes. The principle of photoelectrochemical polymerization is that electrons and holes are produced from the dye excited by light, and the precursor dissolved in the electrolyte solution is oxidized around the dye by way of the applied current or voltage between both electrodes, so that polymerization takes place.

In the operation principle of the dye-sensitized solar cell device thus configured, when light is radiated onto the dye-adsorbed titanium oxide layer, the dye, which absorbed photons, forms excitons and is converted into an excited state from a ground state. The electron-hole pairs are separated, whereby the electrons are injected to the inorganic oxide layer of the semiconductor electrode, and the holes are moved to the hole transport material layer. The injected electrons generate current while being moved to the counter electrode via the wire of an external circuit, and while the electrons, which are reduced by the hole transport material and excited, are moved continuously, a circuit is formed.

In order to increase the light-to-electrical conversion efficiency of the dye-sensitized solar cell, short-circuit current, open-circuit voltage and maximum power have to be raised. Because the solid-state dye-sensitized solar cell has high recombination reactivity between the electrons injected to the semiconductor oxide and the holes moved to the hole transport material, prevention of a recombination reaction greatly contributes to improvements in the above factors. Hence, methods for preventing the recombination of photoelectrons and holes or enhancing the capability of the hole transport material have been developed. First, there are provided techniques for preventing a recombination reaction through an interfacial screening effect by introducing ethyleneglycol for chelating a lithium salt to a dye or a p-type semiconductor hole transport material. Henry J. Snaith, Adam J. Moule, Cedric Klein, Klaus Meerholz, Richard H. Friend, and Michael Gratzel, Nano Letters, 7, 3372 (2007); Taiho Park, Saif A. Hague, Roberto J. Potter, Andrew B. Holmes, and James R. Durrant, Chem. Comm. 11, 2878 (2003). Second, there are provided methods of enhancing short-circuit current and open-circuit voltage while increasing conductivity of a hole transport material using sulfoneimide as the anion of a salt for use in doping a hole transport material for photoelectrochemical polymerization. Jiangbin Xia, Naruhiko Masaki, Monica Lira-Cantu, Yukyeong Kim, Kejian Jiang, and Shozo Yanagida, J. Am. Chem. Soc., 130, 1258 (2008). However, it is difficult to manufacture a solid-state dye-sensitized solar cell satisfying both of the above two advantages.

### DISCLOSURE

### Technical Problem

Accordingly, an object of the present invention is to provide a hole transport material which may reduce a photoelectron recombination reaction and may improve conductivity, and a novel compound therefor.

Another object of the present invention is to provide a solid-state dye-sensitized solar cell, having a polymer layer formed by polymerization of the above compound and drastically increased light-to-electrical conversion efficiency without the use of iodine and an iodine salt.

### Technical Solution

The present invention provides a hole transport material resulting from polymerization of a compound represented by Chemical Formula (1) or (2) below:

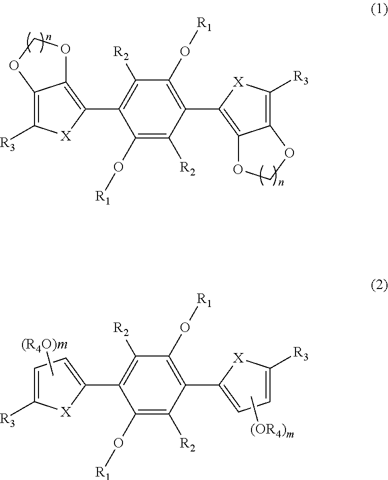

wherein R₁, R₂ and R₄ are each independently hydrogen, an ethyleneglycol oligomer having 1 to 20 carbon atoms, C₁-C₂₀ alkyl, C₁-C₂₀ heteroalkyl, C₃-C₂₀ cycloalkyl, C₁-C₂₀ heterocycloalkyl, C₁-C₂₀ aryl, or C₁-C₂₀ heteroaryl; R₃ is hydrogen or a halide atom; n is a natural number of 1˜5, and a hetero atom may be contained instead of a hydrogen atom; m is 1 or 2; X is a nitrogen atom, a sulfur atom, or a selenium atom.

In Chemical Formula (1) or (2), at least one of R₁, R₂ and R₄ is preferably an ethyleneglycol oligomer having 1 to 20 carbon atoms. More preferably, any one of R₁ and R₂ in Chemical Formula (1) is an ethyleneglycol oligomer having 1 to carbon atoms, and any one of R₁, R₂ and R₄ in Chemical Formula (2) is an ethyleneglycol oligomer having 1 to 20 carbon atoms.

Examples of the compound of Chemical Formula (1) or (2) may include, but are not limited to, 1,4-bis-2-(3,4-ethylenedioxythienyl)-2-(2-methoxyethoxy)benzene, 1,4-bis-2-(3,4-ethylenedioxythienyl)-2-[2-(2-methoxyethoxy)ethoxy]benzene, 1,4-bis-2-(3,4-ethylenedioxythienyl)-2-{2-[2-(2-methoxyethoxy)ethoxy]ethoxy}benzene, 1,4-bis[2-(3,4-ethylenedioxy)thienyl]-2,5-bistriethyleneglycolmethylether benzene (bis-EDOT-TB), 1,4-dibromo-2,5-bis[(3,4-ethylenedioxy)thiophenyl]-2,5-bistetraethyleneglycolbenzene, 1,4-dibromo-2,5-bis[(3,4-ethylenedioxy)thiophenyl]triethyleneglycolbenzene, etc.

The present invention provides a solid-state dye-sensitized solar cell, which has solved the problems of a conventional solution-state dye-sensitized solar cell using iodine and an iodine salt, by subjecting the above compound to photoelectrochemical polymerization or thermal polymerization on the surface of metal oxide to thus form a polymer hole transport material.

In an aspect of the present invention, the solid-state dye-sensitized solar cell includes a semiconductor electrode, a counter electrode and a hole transport material, wherein the semiconductor electrode includes a porous thin film comprising a metal oxide semiconductor and adsorbed with a dye, and a conductive polymer thin film formed thereon by photoelectrochemical polymerization or thermal polymerization of the compound of Chemical Formula (1) and/or (2).

The metal oxide semiconductor is preferably provided in the form of particles, and a dye molecule and a reactive compound are preferably uniformly dispersed in the porous thin film. In the conductive polymer thin film, when R₁, R₂ or R₄ in Chemical Formula (1) or (2) is an ethyleneglycol oligomer having 1 to 20 carbon atoms, chelating of a metal ion becomes possible and improved conductivity after polymerization of the above compound may be obtained. The conductive polymer thin film also enables the dye molecule to be strongly fixed to the surface of metal oxide.

In an aspect of the present invention, the solid-state dye-sensitized solar cell includes a conductive first electrode; an inorganic oxide semiconductor electrode adsorbed with one or more kinds of dye molecules on the first electrode; a conductive material layer comprising the compound of Chemical Formula (1) and/or (2) on the inorganic oxide semiconductor electrode; and a counter electrode comprising a metal on the conductive material layer. The conductive material layer is preferably formed by subjecting the compound of Chemical Formula (1) and/or (2) to photoelectrochemical polymerization or thermal polymerization.

The present invention provides a method of manufacturing a solid-state dye-sensitized solar cell, comprising applying the compound of Chemical Formula (1) and/or (2) on the semiconductor electrode through photoelectrochemical polymerization or thermal polymerization, and positioning and bonding a second electrode thereon or applying a second electrode material.

In an aspect of the present invention, the compound of Chemical Formula (1) is prepared by reacting a compound represented by Chemical Formula (3) below with a compound represented by Chemical Formula (4) below:

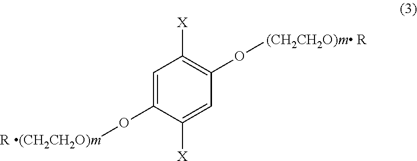

wherein R is hydrogen or alkyl, X is a halogen element, and m is an integer of 1˜10; and

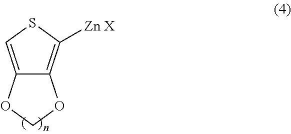

wherein n is an integer of 1˜5, and X is a halogen element.

### Advantageous Effects

According to the present invention, a novel hole transport material is provided, which has a structure for ensuring hole transport capability regarded as important in a solid-state dye-sensitized solar cell and controlling high recombination reactivity depending thereon.

Also according to the present invention, a hole transport material layer is formed around a dye and thus comes into efficient contact with the dye, and furthermore, conductivity can be increased by structural flatness due to ethyleneglycol, and a recombination reaction can be retarded by metal ion chelating, thus improving both short-circuit current and fill factor, ultimately making it possible to manufacture a dye-sensitized solar cell having high efficiency with greatly improved photoelectron conversion efficiency, low cost and long-term stability.

### DESCRIPTION OF DRAWINGS

FIG. 1 is a cross-sectional view illustrating the structure of a dye-sensitized solar cell device manufactured according to an embodiment of the present invention;

FIG. 2 is a cross-sectional view illustrating a titanium oxide electrode having a hole transport material layer manufactured according to an embodiment of the present invention; and

FIG. 3 is a graph illustrating voltage-current properties in the examples of the present invention and comparative examples.

### MODE FOR INVENTION

### A. Hole Transport Material

According to the present invention, a hole transport material is formed using a compound represented by Chemical Formula (1) or (2) below:

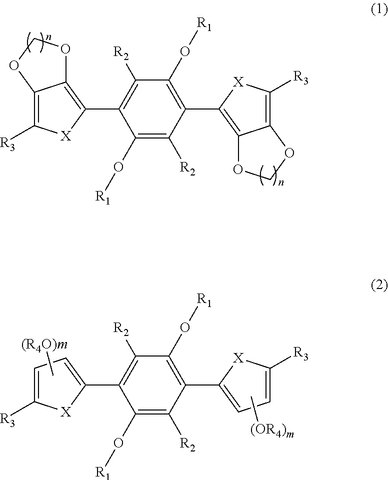

wherein R₁, R₂ and R₄ are each independently hydrogen, an ethyleneglycol oligomer having 1 to 20 carbon atoms, C₁-C₂₀ alkyl, C₁-C₂₀ heteroalkyl, C₃-C₂₀ cycloalkyl, C₁-C₂₀ heterocycloalkyl, C₁-C₂₀ aryl, or C₁-C₂₀ heteroaryl; R₃ is hydrogen or a halide atom; n is a natural number of 1˜5, and a hetero atom may be contained instead of a hydrogen atom; m is 1 or 2; X is a nitrogen atom, a sulfur atom, or a selenium atom.

In the substituents of Chemical Formula (1) or (2), any one of R₁, R₂ and R₄ is preferably an ethyleneglycol oligomer having 1 to 20 carbon atoms.

Examples of the compound include 1,4-bis-2-(3,4-ethylenedioxythienyl)-2-(2-methoxyethoxy)benzene, 1,4-bis-2-(3,4-ethylenedioxythienyl)-2-[2-(2-methoxyethoxy)ethoxy]benzene, 1,4-bis-2-(3,4-ethylenedioxythienyl)-2-{2-[2-(2-methoxyethoxy)ethoxy]ethoxy}benzene, 1,4-bis[2-(3,4-ethylenedioxy)thienyl]-2,5-bistriethyleneglycolmethylether benzene (bis-EDOT-TB), 1,4-dibromo-2,5-bis[(3,4-ethylenedioxy)thiophenyl]-2,5-bistetraethyleneglycolbenzene, 1,4-dibromo-2,5-bis[(3,4-ethylenedioxy)thiophenyl]triethyleneglycolbenzene, etc.

### B. Synthesis of Compound

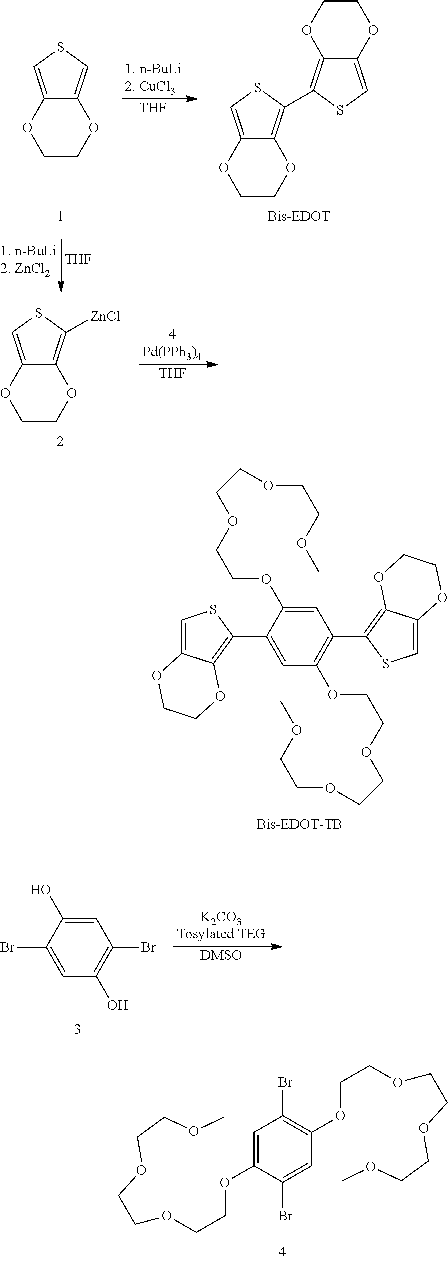

### Bis-EDOT) 2,2′-Bis(3,4-ethylenedioxythiophene)

In a round-bottom flask, 30 mL of anhydrous THF and 7.0 mM 3,4-ethylenedioxythiophene (1) are placed, and then the inside of the flask is purged with nitrogen gas. The aforementioned solution is cooled to −78° C., 7 mL of 2.5 M butyllithium is slowly added dropwise, and stirring is then performed for 45 min. When the solution turns transparent yellow, 7.0 mM CuCl₂ is added at a time, and the temperature is gradually increased to 45° C. and stirring is conducted at the same temperature for 2 hr. After completion of the reaction, THF is removed using a vacuum rotary evaporator, and the organic solution layer is then extracted with distilled water and dichloromethane. The extracted solution is removed once more using a vacuum rotary evaporator, followed by column chromatography using chloroform as a developer on dry silica gel, yielding a white solid. Yield: 70%; mp 183˜185° C.; ¹H NMR (CDCl₃) δ 6.93 (s, 2H), 4.34-4.32 (m, 4H), 4.25-4.23 (m, 4H); the other data corresponds to data of the following reference: Sotzing, G. A., Reynolds, J. R., and Steel, P. J., Adv. Mater., 9, 795-798 (1997).

### Tosylated TEG) Triethyleneglycolmethylester sulfonetoluene

50 mL of a dichloromethane solvent is added with 57.8 mM tosyl chloride and then stirred. With stirring at 0° C., a solution of 61 mM triethyleneglycolmethylether and 91.3 mM triethylamine dissolved in 100 mL of dichloromethane is slightly added dropwise, and stirring is further performed for 5 hr. After completion of the reaction, the resulting reaction product is poured on 0.1 M aqueous hydrochloric acid to remove unreacted material, followed by extraction of the water layer with dichloromethane. The collected organic layer is dewatered using magnesium sulfate, yielding a pale yellow material using a vacuum rotary evaporator. Yield: 93%, ¹H NMR (DMSO d₆) δ 7.76-7.79 (d, 2H), 7.46-7.49 (d, 2H), 4.08-4.11 (t, 2H), 3.54-3.57 (t, 2H), 3.33-3.47 (m, 8H), 3.23 (s, 3H), 2.41 (s, 3H). The other data corresponds to data of the following reference: Gentilini, C., Boccalan, M., and Pasquato, L., Eur. J. Org. Chem., 3308 (2008).

### 4) 1,4-Dibromo-2,5-bis-triethyleneglycolmethylether benzene

To 30 mL of an ethanol solution containing 50 mM potassium hydroxide, a solution of 24.5 mM 1,4-dibromo-2,5-hydroxybenzene (3) dissolved in 60 mL of THF is slowly added in a nitrogen atmosphere. After stirring at room temperature for 3 hr, 50 mM triethyleneglycolmethylester sulfonetoluene is dissolved in 60 mL of THF and then slowly added, and the reaction mixture is warmed to 50° C. and stirred for 24 hr. After completion of the reaction, aqueous sodium chloride and ether are added, and thus the organic layer is separated and then dewatered with magnesium sulfate. Thereafter, column chromatography is performed using, as a developer, a solution of hexane and ethylacetate at 1:1, yielding a pale yellow liquid. Yield: 91%; ¹H NMR (CDCl₃) δ 7.31 (s, 2H), 3.76-3.80 (t, 4H), 3.61-3.66 (m, 12H), 3.52-3.54 (t, 4H), 3.42-3.46 (t, 4H), 3.36 (s, 6H); ¹³C NMR (CDCl₃) δ 150.3, 119.2, 111.4, 71.9, 71.1, 70.7, 70.6, 70.2, 69.6, 59.0; Elem. anal. calcd for C, 42.87; H, 5.76. found for C, 42.87; H, 5.76; m/e calcd for C₂₀H₃₂Br₂O₈, 558.0464. found for 559.0440 ([M]+).

### Bis-EDOT-TB) 1,4-Bis[2-(3,4-ethylenedioxy)thienyl]-2,5-bistriethyleneglycolmethylether benzene

30 mL of butyllithium is slowly added dropwise to a solution of 30 mM EDOT dissolved in 75 mL of THF at −78° C. in a nitrogen atmosphere. When the color of the solution turns yellow, the solution is slowly added over 20 min to a solution of 33 mM ZnCl₂ dissolved in 75 mL of THF, followed by stirring for 1 hr, thus obtaining a mixture of EDOT-ZnCl (2). Subsequently, this mixture is slowly added to a solution of 6.91 mM 1,4-dibromo-2,5-bis-triethyleneglycolmethylether benzene and 0.03 mM Pd(PPh₃)₄ dissolved in 50 mL of THF, and the solution is gradually warmed to 50° C. and then stirred for three days. After completion of the reaction, the unreacted material is removed with 1 M aqueous hydrochloric acid, and the reaction product is extracted with dichloromethane and dewatered with magnesium sulfate. Subsequent filtration using a silica pad and recrystallization from dichloromethane are implemented, yielding orange crystals. Yield: 84%; mp 85.0˜86.2; ¹H NMR (CDCl₃) δ 7.69 (s, 2H), 6.36 (s, 2H) 4.31-4.29 (m, 4H), 4.26-4.24 (m, 4H), 4.22-4.20 (t, 4H), 3.96-3.93 (t, 4H), 3.77-3.74 (m, 4H), 3.69-3.63 (m, 8H), 3.55-3.52 (m, 4H), 3.37 (s, 6H); ¹³C NMR (CDCl₃); Elem. Anal. calcd for C, 56.29; H, 6.20; S, 9.39. found for C, 56.28; H, 6.16, S, 9.37; m/e calcd for C₃₂H₄₂O₁₂S₂, 682.2118. found for 683.4300 ([M]+).

### C. Structure and Manufacture of Solid-State Dye-Sensitized Solar Cell

FIG. 1 schematically illustrates the layer structure of a solid-state dye-sensitized solar cell device according to an embodiment of the present invention, wherein a conductive hole transport material layer formed by photoelectrochemical polymerization or thermal polymerization of the compound of Chemical Formula (1) or (2) according to the present invention is applied on a metal oxide semiconductor electrode adsorbed with a dye molecule. As illustrated in FIG. 1, the dye-sensitized solar cell includes a first electrode 1002 on a first substrate 1001 which is a transparent substrate, and an inorganic oxide layer 1003, a dye layer 1004, an ethyleneglycol-introduced conductive hole transport material layer 1005, an ionic electrolyte/additive layer 1006, and a second electrode 1007, which are sequentially formed on the first electrode 1002. The second electrode 1007 is provided in the form of a multilayer thin film coated with a metal such as gold (Au) or silver (Ag).

The first substrate 1001 may be formed of glass, or a transparent polymer material such as PET (polyethylene terephthalate), PEN (polyethylene naphthalate), PP (polypropylene), PI (polyamide) or TAC (triacetyl cellulose). The substrate is preferably made of glass.

The first electrode 1002 is a transparent metal oxide electrode formed on one surface of the first substrate 1001 which is transparent. The first electrode 1002 plays a role as an anode. The first electrode has a work function smaller than that of the second electrode 1007 and has transparency and conductivity. The first electrode 1002 may be formed by being applied on one surface of the first substrate 1001 by means of a process known in the art such as sputtering, spin coating, etc. Examples of the material for the first electrode 1002 may include ITO (indium-tin oxide), FTO (fluorine doped tin oxide), ZnO—Ga₂O₃, ZnO—Al₂O₃, SnO₂—Sb₂O₃, etc. Preferably useful is ITO or FTO.

The inorganic oxide layer 1003 of the device is preferably made of metal oxide in the form of nanoparticles. Examples of the metal oxide include transition metal oxides, such as titanium oxide, scandium oxide, vanadium oxide, zinc oxide, gallium oxide, yttrium oxide, zirconium oxide, niobium oxide, molybdenum oxide, indium oxide, tin oxide, lanthanide oxide, tungsten oxide, and iridium oxide, alkaline earth metal oxides such as magnesium oxide and strontium oxide, aluminum oxide, etc. Preferably, the material of the inorganic oxide layer is titanium oxide in the form of nanoparticles.

The inorganic oxide layer 1003 is applied on the first electrode 1002 by coating one surface of the first electrode 1002 with a paste including an inorganic oxide and then thermally treating it. Typically, the paste is applied to a thickness of about 5˜30 μm and preferably about 10˜15 μm on one surface of the first electrode 1002 using a doctor blade process or a screen printing process. In addition thereto, spin coating, spraying, wet coating, etc. may be used, as understood by those skilled in the art.

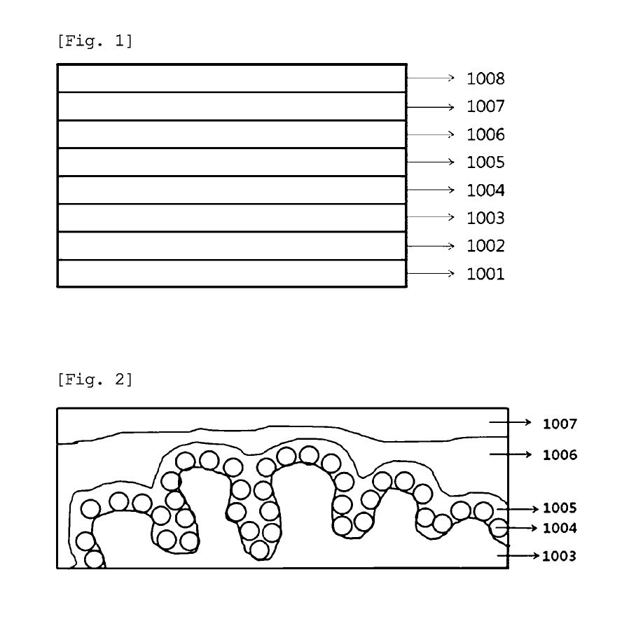

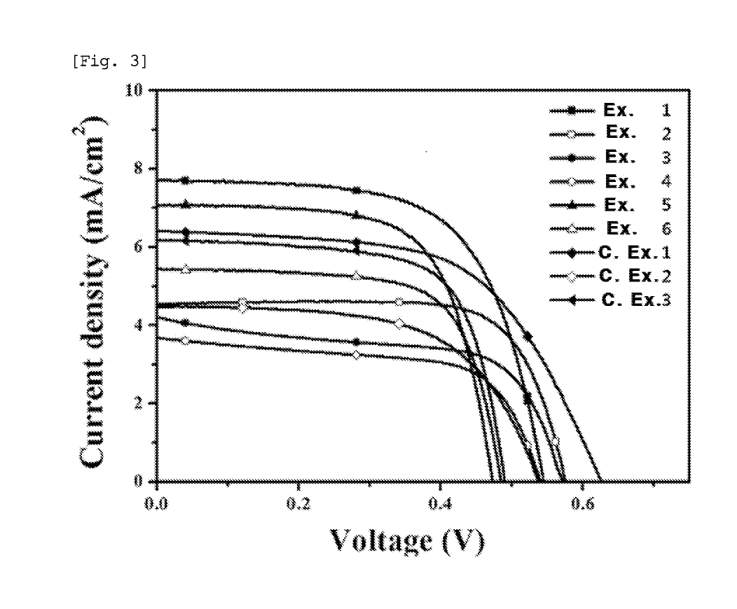

The dye layer 1004 is formed by chemical adsorption of a photosensitive dye on the inorganic oxide layer 1003. As illustrated in FIG. 2, the photosensitive dye adsorbed on the inorganic oxide layer 1003 which is a porous film is preferably a material able to absorb light in the UV and visible ranges. Such a material is exemplified by a photosensitive dye such as a ruthenium complex, for instance, Ruthenium 535, Ruthenium 535 bis-TBA, Ruthenium 620-1H3TBA, etc. The dye is preferably Ruthenium 535 bis-TBA. The photosensitive dye which may be chemically adsorbed on the inorganic oxide layer 1003 may include, in addition to the ruthenium-based dye, any dye having a charge separation function, for example, a xanthene-based dye, a cyanine-based dye, a porphyrin-based dye, an anthraquinone-based dye, an organic dye, etc.

The dye may be adsorbed on the inorganic oxide layer 1003 using a typical process. Preferably, the dye is adsorbed in such a manner that it is dissolved in a solvent such as alcohol, nitrile, hydrocarbon halide, ether, amide, ester, ketone, N-methylpyrrolidone, etc. or is dissolved in a co-solvent of acetonitrile and t-butanol, and then a photoelectrode coated with the inorganic oxide layer 1003 is immersed in the dye solution.

The ethyleneglycol-introduced hole transport material layer 1005, which is responsible for performing hole transport of the device and preventing recombination, is formed on the dye-adsorbed inorganic oxide layer 1003. The hole transport material layer 1005 may be formed from the compound of Chemical Formula (1) or (2) using photopolymerization.

In the ionic electrolyte/additive layer 1006 of the device according to the present invention, the useful anion is BF₄⁻, ClO₄⁻, Br⁻, (CF₃SO₂)²N⁻ and so on, and is coupled with a cation for an ionic electrolyte, for example, an ammonium compound such as imidazolium, tetra-alkyl ammonium, pyridinium, triazolium, etc. and is thus provided in the form of a salt, but the present invention is not limited thereto. Also, such a compound may be used in a mixture of two or more. The metal cation of the metal salt may include Li, Na, K, Mg, Ca, Cs, etc.

Particularly preferably useful is an ionic liquid electrolyte comprising a combination of Li(CF₃SO₂)₂N and imidazolium bistrifluorosulfoneimide. Examples of the compound useful as the ionic liquid in the electrolyte usable in the present invention may include n-methylimidazolium bistrifluorosulfoneimide, n-ethylimidazolium bistrifluorosulfoneimide, 1-benzyl-2-methylimidazolium bistrifluorosulfoneimide, 1-ethyl-3-methylimidazolium bistrifluorosulfoneimide, 1-butyl-3-methylimidazolium bistrifluorosulfoneimide, etc. Particularly preferably useful is 1-ethyl-3-methylimidazolium bistrifluorosulfoneimide, which may be used in a combination with Li(CF₃SO₂)₂N. In the case where such an ionic liquid, that is, a dissolved salt, is used, a solid electrolyte wherein a solvent is not used in an electrolyte composition may be formed.

The second electrode 1007 may be applied on the other surface of the second substrate 1008 or on the ionic liquid electrolyte/additive layer 1006, and may be used as the cathode of the device. The second electrode 1007 may be applied on the other surface of the second substrate 1008 by way of sputtering or spin coating, or may be applied on the ionic liquid electrolyte/additive layer 1006 using brushing.

The material for the second electrode 1007 has a work function greater than that of the material for the first electrode 1002, and examples thereof may include platinum (Pt), gold (Au), silver (Ag), carbon (C), etc. Preferably useful is silver (Ag). The second substrate 1008 is made of a transparent material similar to that of the first substrate 1001, and may be formed using a transparent material, such as glass, or a plastic including PET, PEN, PP, PI, TAC, etc. Preferably useful is glass.

Meanwhile, electrons are transferred to the inorganic oxide from the dye excited by light, and holes are moved to the hole transport material from the oxidized dye. Accordingly, the hole transport material layer 1005 receives electrons from the ionic electrolyte/additive layer 1006 and the second electrode 1007 to thus complete a circuit of the device.

Below is a description of the process of manufacturing the dye-sensitized solar cell device according to an embodiment of the present invention.

Specifically, an inorganic oxide which is exemplified by titanium oxide in a colloidal state is preferably applied or cast to a thickness of about 5˜30 an on the first substrate 1001 such as transparent glass coated with a first electrode material such as ITO or FTO, and burned at about 450˜550° C., thus forming a photoelectrode in which the organic material-free first substrate 1001, the first electrode 1002 and the inorganic oxide layer 1003 are sequentially applied/stacked. Subsequently, in order to adsorb a dye on the formed inorganic oxide layer 1003, the dye, for example, Ruthenium Z907, is added to a prepared ethanol solution to obtain a dye solution, after which the photoelectrode corresponding to the transparent substrate coated with the inorganic oxide layer is immersed in the dye solution so that the dye is adsorbed, thereby forming a dye layer 1004.

Thereafter, the dye-adsorbed transparent substrate is immersed in a solution containing a hole transport material precursor represented by Chemical Formula (1) or (2) according to the present invention at a molar fraction of about 0.005˜0.05 and a metal salt electrolyte at a molar fraction of about 0.05˜1, after which light and voltage are applied, so that the precursor is polymerized, thereby forming a hole transport material layer 1005. The ionic liquid electrolyte/metal salt additive layer 1006 is applied on the hole transport material-applied semiconductor electrode, and then bonded with the second electrode 1007 formed on the second substrate 1008 or a material for the second electrode 1007 is applied, thereby manufacturing a solid-state dye-sensitized solar cell device.

### EXAMPLES

### Example 1

A composition for forming a TiO₂ (Solaronix) porous film was applied on a transparent glass substrate coated with fluorine-doped ITO having a substrate resistance of 15Ω/□ using a doctor blade process. Drying and then thermal treatment at 500° C. for 30 min were performed, thus forming a porous film containing TiO₂. The thickness of the porous film was about 6 μm. Subsequently, a first electrode comprising the above porous film was immersed for 18 hr in a solution of 0.30 mM ruthenium (4,4-dicarboxy-2,2′-bipyridyl)(4,4-dinonyl-22bipyridyl) (NCS) as a dye in acetonitrile and tert-butanol (1:1 volume ratio) as a solvent, so that the dye was adsorbed on the porous film. Subsequently, the first electrode comprising the dye-adsorbed porous film was immersed in a solution of 0.1 M lithium bistrifluorosulfoneimide electrolyte and 0.01 M 1,4-bis[2-(3,4-ethylenedioxy)thienyl]-2,5-bistriethyleneglycolmethylether benzene (bis-EDOT-TB) dissolved in acetonitrile, after which, with light being radiated onto the back surface of the first electrode at an intensity of 22 mW and a wavelength of 520˜1000 nm, a platinum wire was connected to a counter electrode and a voltage of +0.2 V was applied based on an Ag/AgC1 reference electrode, so that a photoelectrochemical reaction was carried out for 20 min. Three drops of an 1-ethyl-3-methylimidazolium bistrifluorosulfoneimide ionic liquid electrolyte containing 0.2 M lithium bistrifluorosulfoneimide and tert-butylpyridine were added onto the hole transport material-applied semiconductor electrode, after which the semiconductor electrode was stored in a nitrogen atmosphere for 24 hr.

Before application of a second electrode, the ionic liquid electrolyte layer of the semiconductor electrode was wiped using a WypAll wiper, thus forming a thin film, on which a silver paste was then applied and dried and a silver wire was attached using a paste, thereby manufacturing a solid-state dye-sensitized solar cell.

### Example 2

This example is the same as Example 1, except for carrying out the photoelectrochemical reaction for 30 min.

### Example 3

This example is the same as Example 2, except for using 1,4-bis-2-(3,4-ethylenedioxythienyl)-2-{2-[2-(2-methoxyethoxy)ethoxy]ethoxy}benzene having a different structure from the hole transport material precursor used in Example 1 and for carrying out the photoelectrochemical reaction under the same conditions to thus manufacture a solid-state dye-sensitized solar cell.

### Example 4

This example is the same as Example 3, except for carrying out the photoelectrochemical reaction for 30 min.

### Example 5

Onto the first electrode comprising the dye-adsorbed porous film of Example 1, a few drops of a solution of 0.01 M 1,4-dibromo-2,5-bis[(3,4-ethylenedioxy)thiophenyl]-2,5-bistetraethyleneglycolbenzene dissolved in ethanol were added, followed by thermal polymerization at 80° C. for 30 min. Subsequently, a few drops of the above solution were added onto the manufactured film, and then thermal polymerization at 80° C. for 24 hr was implemented, after which the same subsequent procedures as in Example 1 were performed, thus manufacturing a solid-state dye-sensitized solar cell.

### Example 6

1,4-dibromo-2,5-bis[(3,4-ethylenedioxy)thiophenyl]triethyleneglycolbenzene having a different structure from the hole transport material precursor used in Example 5 was used.

### Comparative Example 1

A composition for forming a TiO₂ (Solaronix) porous film was applied on a transparent glass substrate coated with fluorine-doped ITO having a substrate resistance of 15Ω/□ using a doctor blade process. Drying and then thermal treatment at 500° C. for 30 min were performed, thus forming a porous film containing TiO₂. The thickness of the porous film was about 6 μm. Subsequently, a first electrode comprising the above porous film was immersed for 18 hr in a solution of 0.30 mM ruthenium (4,4-dicarboxy-2,2′-bipyridyl)(4,4-dinonyl-22bipyridyl) (NCS) as a dye in acetonitrile and tert-butanol (1:1 volume ratio) as a solvent, so that the dye was adsorbed on the porous film. Subsequently, the first electrode comprising the dye-adsorbed porous film was immersed in a solution of 0.1 M lithium bistrifluorosulfoneimide electrolyte and 0.01 M bis-3,4-ethylenedioxythiophene dissolved in acetonitrile, after which, with light being radiated onto the back surface of the first electrode at an intensity of 22 mW and a wavelength of 520-1000 nm, a platinum wire was connected to a counter electrode and a voltage of +0.2 V was applied based on an Ag/AgCl reference electrode, so that a photoelectrochemical reaction was carried out for 20 min. Onto the hole transport material-applied semiconductor electrode, three drops of an 1-ethyl-3-methylimidazolium bistrifluorosulfoneimide ionic liquid electrolyte containing 0.2 M lithium bistrifluorosulfoneimide and tert-butylpyridine were added, after which the semiconductor electrode was stored in a nitrogen atmosphere for 24 hr.

Before application of a second electrode, the ionic liquid electrolyte layer of the semiconductor electrode was wiped using a WypAll wiper, thus forming a thin film, on which a silver paste was then applied and dried and a silver wire was attached using a paste, thereby manufacturing a solid-state dye-sensitized solar cell.

### Comparative Example 2

This comparative example is the same as Comparative Example 1, except for carrying out the photoelectrochemical reaction for 30 min.

### Comparative Example 3

Onto the first electrode comprising the dye-adsorbed porous film of Comparative Example 1, a few drops of a solution of 0.01 M 2,5-dibromo-3,4-ethylenedioxythiophene dissolved in ethanol were added, followed by thermal polymerization at 80° C. for 30 min. Subsequently, a few drops of the above solution were added onto the manufactured film, and then thermal polymerization at 80° C. for 24 hr was implemented, after which the same subsequent procedures as in Comparative Example 1 were performed, thus manufacturing a solid-state dye-sensitized solar cell.

The properties of the solid-state dye-sensitized solar cells manufactured in the examples and the comparative examples are given in Table 1 below. The current density is graphed in FIG. 3.

TABLE 1

| | Open-circuit | Short-circuit | | Efficiency |
|---|---|---|---|---|
| | voltage (V) | current (mA/cm²) | Fill factor | (%) |
| Ex. 1 | 0.543 | 7.7 | 64.3 | 2.7 |
| Ex. 2 | 0.570 | 4.6 | 74.4 | 1.9 |
| Ex. 3 | 0.523 | 1.2 | 69.4 | 0.4 |
| Ex. 4 | 0.585 | 1.1 | 68.8 | 0.5 |
| Ex. 5 | 0.473 | 7.1 | 67.2 | 2.2 |
| Ex. 6 | 0.485 | 5.4 | 69.4 | 1.8 |
| C. Ex. 1 | 0.385 | 3.6 | 40.0 | 0.6 |
| C. Ex. 2 | 0.543 | 4.5 | 60.0 | 1.5 |
| C. Ex. 3 | 0.489 | 6.2 | 68.7 | 2.1 |

Evaluation and Discussion

The hole transport material according to the present invention has a structure for ensuring hole transport capability regarded as important in a solid-state dye-sensitized solar cell and controlling high recombination reactivity depending thereon. The holes produced by the excited dye are transferred to the hole transport material layer, and as such holes are quickly moved away from the interface, a recombination reaction may be reduced. Likewise, by virtue of the charge screening effect of the cation of the metal salt due to metal chelating, recombination of electrons and holes is retarded. Thereby, both short-circuit current and fill factor may be improved, thus increasing photoelectron conversion efficiency. Therefore, the present invention can provide a technique for development of a high-efficiency solid-state dye-sensitized solar cell.

Although the preferred embodiments of the present invention have been disclosed for illustrative purposes, those skilled in the art will appreciate that various modifications, additions and substitutions are possible, without departing from the scope and spirit of the invention as disclosed in the accompanying claims, detailed description and drawings.

1. A compound represented by Chemical Formula (1) or (2) below: 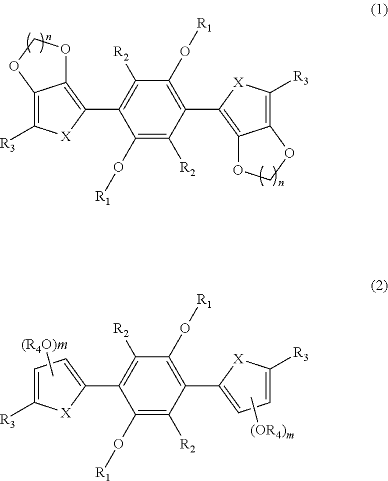
wherein R₁, R₂ and R₄ are each independently hydrogen, an ethyleneglycol oligomer having 1 to 20 carbon atoms, a propyleneglycol oligomer having 1 to 20 carbon atoms, C₁-C₂₀ alkyl, C₁-C₂₀ heteroalkyl, C₃-C₂₀ cycloalkyl, C₁-C₂₀ heterocycloalkyl, C₁-C₂₀ aryl, or C₁-C₂₀ heteroaryl; R₃ is hydrogen or a halide atom; n is a natural number of 1 to 5, and a hetero atom is able to be contained instead of a hydrogen atom; m is 1 or 2; X is a nitrogen atom, a sulfur atom, or a selenium atom.

2. The compound of claim 1, wherein any one of R₁ and R₂ in Chemical Formula (1) is an ethyleneglycol oligomer having 1 to 20 carbon atoms, and any one of R₁, R₂ and R₄ in Chemical Formula (2) is an ethyleneglycol oligomer having 1 to 20 carbon atoms.

3. The compound of claim 1, wherein the compound is:
1,4-bis-2-(3,4-ethylenedioxythienyl)-2-(2-methoxyethoxy)benzene,
1,4-bis-2-(3,4-ethylenedioxythienyl)-2-[2-(2-methoxyethoxy)ethoxy]benzene,
1,4-bis-2-(3,4-ethylenedioxythienyl)-2-{2-[2-(2-methoxyethoxy)ethoxy]ethoxy}benzene,
1,4-bis[2-(3,4-ethylenedioxy)thienyl]-2,5-bistriethyleneglycolmethylether benzene,
1,4-dibromo-2,5-bis[(3,4-ethylenedioxy)thiophenyl]-2,5-bistetraethyleneglycolbenzene, or
1,4-dibromo-2,5-bis[(3,4-ethylenedioxy)thiophenyl]triethyleneglycolbenzene.

4. The compound of claim 1, wherein the compound is 1,4-bis[2-(3,4-ethylenedioxy)thienyl]-2,5-bistriethyleneglycolmethylether benzene.

5. A solution, comprising a compound of claim 1.

6. The solution of claim 5, wherein the compound has a molar concentration of 0.005 to 0.5.

7. The solution of claim 5, wherein the solution comprises a lithium (Li) electrolyte.

8. A solid-state dye-sensitized solar cell, comprising an inorganic oxide semiconductor electrode adsorbed with a dye, and a hole transport layer formed thereon by polymerization of at least one compound of claim 1.

9. The solid-state dye-sensitized solar cell of claim 8, wherein the inorganic oxide semiconductor electrode comprises TiO₂ nanoparticles.

10. The solid-state dye-sensitized solar cell of claim 8, wherein the dye comprises a ruthenium-based dye, a xanthene-based dye, a cyanine-based dye, a porphyrin-based dye, an anthraquinone-based dye, or an organic dye.

11. The solid-state dye-sensitized solar cell of claim 8, wherein the hole transport layer is doped with a Li ion.

12. The solid-state dye-sensitized solar cell of claim 8, wherein an ionic liquid electrolyte layer is formed on the hole transport layer.

13. The solid-state dye-sensitized solar cell of claim 8, wherein the hole transport layer is a photoelectrochemical polymerization layer.

14. A method of manufacturing a solid-state dye-sensitized solar cell, the method comprising:
forming a hole transport layer comprising at least one compound of claim 1 on an inorganic oxide semiconductor electrode adsorbed with a dye molecule;
forming an ionic liquid electrolyte layer on the hole transport layer; and
forming a second electrode.

15. The method of claim 14, wherein forming the hole transport layer comprises subjecting the compound to photoelectrochemical polymerization or thermal polymerization.

16. The method of claim 14 or 15, wherein the ionic liquid electrolyte comprises a Li ion.

17. A method of preparing the compound of Chemical Formula (1) of claim 1, comprising reacting a compound represented by Chemical Formula (3) below: 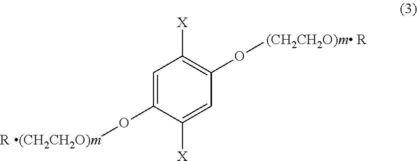
with a compound represented by Chemical Formula (4) below: 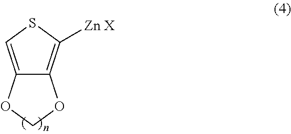
wherein R is hydrogen or alkyl, X is a halogen element, and m is an integer of 1 to 10; and
wherein n is an integer of 1 to 5, and X is a halogen element.

18. A compound represented by Chemical Formula (3) below: 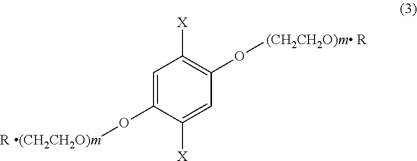
wherein R is hydrogen or alkyl, X is a halogen element, and m is an integer of 1 to 10.
